(19) United States
(12) Patent Application Publication
(10) Pub. No.: US 2006/0067036 A1
(43) Pub. Date: Mar. 30, 2006

(54) Display

(75) Inventors: Chi-Cheng Lin, Taoyuan (TW); Man-Wai Wong, Taoyuan (TW)

Correspondence Address: QUINTERO LAW OFFICE, 1617 BROADWAY, 3RD FLOOR, SANTA MONICA, CA, 90404, US

(73) Assignee: BENQ CORPORATION, TAOYUAN (TW)

(21) Appl. No.: 11/282,260

(22) Filed: Nov. 18, 2005

Related U.S. Application Data
(62) Division of application No. 10/726,725, filed on Dec. 3, 2003.

(30) Foreign Application Priority Data
Mar. 27, 2003 (TW) TW92106919

(51) Int. Cl. H05K 7/00

(52) U.S. Cl. 361/681

(57) ABSTRACT

A display. The display includes a base and a panel. The base has a first connector, the panel has a second connector, and the panel and base are detachably connected along a vertical axis. The panel faces either a first or a second direction with respect to a horizontal axis on the base. When the panel is connected to the base and faced to the first direction, the first connector is electrically connected to the second connector.

### BACKGROUND OF THE INVENTION

1. Field of the Invention

The present invention relates to a display, and in particular to a rotatable and detachable display for an electronic device.

2. Description of the Related Art

Current electronic products, in addition to small and light requirements, need to provide good display quality. Electronic devices such as VCD/DVD player, mobile phone, electronic calculator, personal digital assistant (PDA), electronic dictionary, electronic book or other portable electronic products, all equip with a display. Most of these displays are mainly designed for direct viewing only, making it difficult for other users to view from different directions. Further, it is inconvenient for turning these displays to different directions to make displayed content be available to others.

FIG. 1a is a schematic view of a conventional portable computer. The portable computer 10 has a display 102 and a body 104, connected by a hinge 106, allowing rotation through only a single axis, and not beyond 180°.

FIG. 1b is another schematic view showing another conventional portable computer. The portable computer 10 also has a display 102 and a body 104, connected by hinges 106, 108. Display 102 can be rotated around X-axis by the hinge 106 and around Y-axis by the hinge 108. In addition, wires (not shown) connecting the display 102 and the body 104 will constrain the rotating angles of the display 102. Thus, this display 102 is not freely rotatable through 360°.

Hence, there remains a need for a design that modifies and maximizes the rotating angle of the conventional display.

### SUMMARY OF THE INVENTION

Accordingly, an object of the invention is to provide a display rotatably and detachably disposed on a base of a computer or other electronic products.

Another object of the invention is to provide a display to rotate freely without using two hinges.

Another object of the invention is to provide a display unrestricted by wires between the display and the body, thereby rotating at any angle.

The present invention provides a display, including a base and a panel. The base has a first connector. The panel has a second connector. The panel and the base are detachably connected along a vertical axis. The panel faces to a first direction or a second direction respect to a horizontal axis while connecting with the base. The first direction is opposite to the second direction. Further, the first connector is electrically connected with the second connector when the panel faces to the first direction to connect with the base.

According to the first aspect of the present invention, the panel has a protrusion, and the base defines a groove therein for receiving the protrusion to connect the panel to the base. The second connector is disposed on the protrusion of the panel, and the first connector is disposed in the groove of the base, such that the first connector is electrically connected with the second connector when the panel connects to the base in either the first or the second direction.

Accordingly, the base has a third connector, the first and the third connector of the base are disposed in the groove, and the second connector is disposed on the protrusion of the panel. Therefore, the second connector is electrically connected with the first connector when the panel is faced to the first direction to engage with the base, and the second connector is electrically connected with the third connector when the panel is faced to the second direction to engage with the base.

Accordingly, the panel further has a third connector, and the second and third connectors are disposed on the protrusion of the panel. The first connector is disposed in the groove of the base. Therefore, the first connector is electrically connected with the second connector when the panel is faced to the first direction to engage with the base, and the first connector is electrically connected with the third connector when the panel is faced to the second direction to engage with the base.

According to the second aspect of the present invention, the base has a protrusion, and the panel defines a groove therein for receiving the protrusion to connect the panel to the base. The first connector is disposed on the protrusion of the base, and the second connector is disposed in the groove of the panel. Therefore, the first connector is electrically connected with the second connector when the panel connects to the base in either the first or the second direction.

Accordingly, the panel further has a third connector, the second and the third connectors are disposed in the groove of the panel, and the first connector is disposed on the protrusion of the base. Therefore, the first connector is electrically connected with the second connector when the panel is faced to the first direction to engage with the base, and the first connector is electrically connected with the third connector when the panel is faced to the second direction to engage with the base.

Accordingly, the base further has a third connector, the first and third connectors are disposed on the protrusion of the base, and the second connector is disposed in the groove of the panel. Therefore, the second connector is electrically connected with the first connector when the panel is faced to the first direction to engage with the base, and the second connector is electrically connected with the third connector when the panel is faced to the second direction to engage with the base.

Furthermore, the display further includes a wire electrically connected the panel to the base.

The display further includes a body to control the display and a shaft connecting the base to the body.

According to the third aspect of the present invention, the display includes a frame and a panel. The panel has a first shaft which is rotatably disposed within the frame. The panel is rotated freely by a Y-axis direction via the first shaft, so that the panel is operated when facing to a first or a second direction. The first direction is opposite to and the second direction.

Accordingly, the frame has a first connector and the panel has a second connector. When the panel faces the first direction, the first connector is electrically connected with the second connector. The frame has a third connector. The first connector is electrically connected with the second connector when the panel is faced to the first direction, and the second connector is electrically connected with the third connector when the panel faces the second direction.

Accordingly, the frame has a third connector, the first connector is electrically connected with the second connector when the panel is faced to the first direction, and the second connector is electrically connected with the third connector when the panel faces the second direction.

Accordingly, the panel has a third connector. The first connector is electrically connected with the second connector when the panel is faced to the first direction, and the second connector is electrically connected with the third connector when the panel faces the second direction.

Furthermore, the display further includes a body and a second shaft. The frame is rotatably connected to the body. The panel is rotatably connected to the frame via the second shaft. The frame is rotated freely by the X-axis, and the panel is freely rotated about the Y-axis. In addition, the first shaft is hollow, and the display further has a wire disposed in the first shaft to electrically connect the panel to the base.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1A is a schematic view of a conventional portable computer;

FIG. 1B is another schematic view showing another conventional portable computer;

FIGS. 2A˜2D are schematic views of the display according to the first embodiment of the present invention;

FIG. 2E is an enlarged view of the base according to the first embodiment of the present invention;

FIG. 2F is a schematic back view of the simplified display according to the first embodiment of the present invention;

FIGS. 3A˜3D are schematic views of the display according to the second embodiment of the present invention;

FIG. 3E is a schematic view of the display and the base according to the second embodiment of the present invention;

FIG. 3F is a schematic back view of the simplified display according to the second embodiment of the present invention;

FIG. 4 is a schematic view of the display with a wire according to the third embodiment of the present invention;

FIG. 5a is a schematic front view of the display according to the fourth embodiment of the present invention; and

FIG. 5b is a schematic back view of the display according to the fourth embodiment of the present invention.

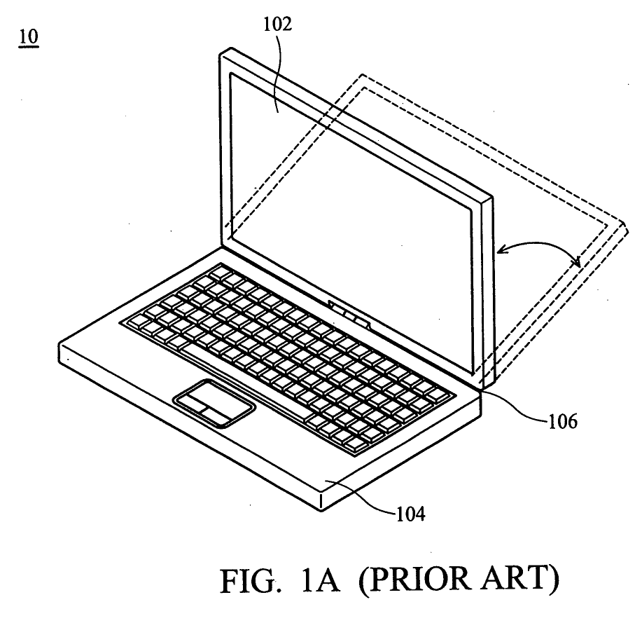

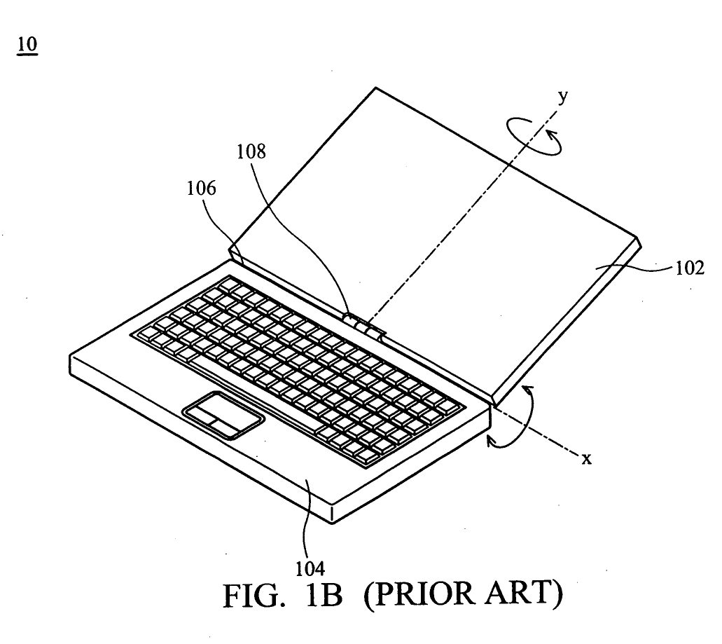

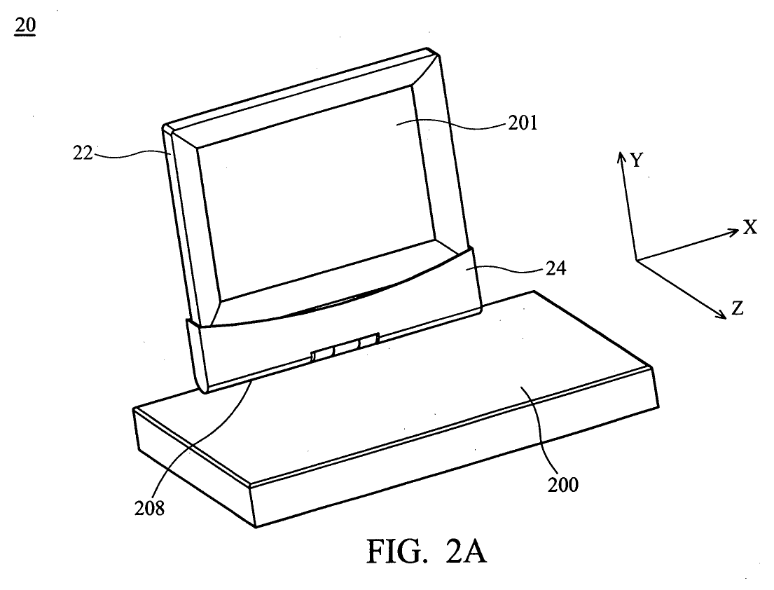

### DETAILED DESCRIPTION OF THE INVENTION

The display of the present invention is applicable to various electronic devices, such as liquid crystal displays (LCD) for desktop PC, notebook, mobile phone, VCD/DVD player, personal digital assistant (PDA), electronic calculator, electronic dictionary, electronic book, or other portable electronic products.

### First Embodiment

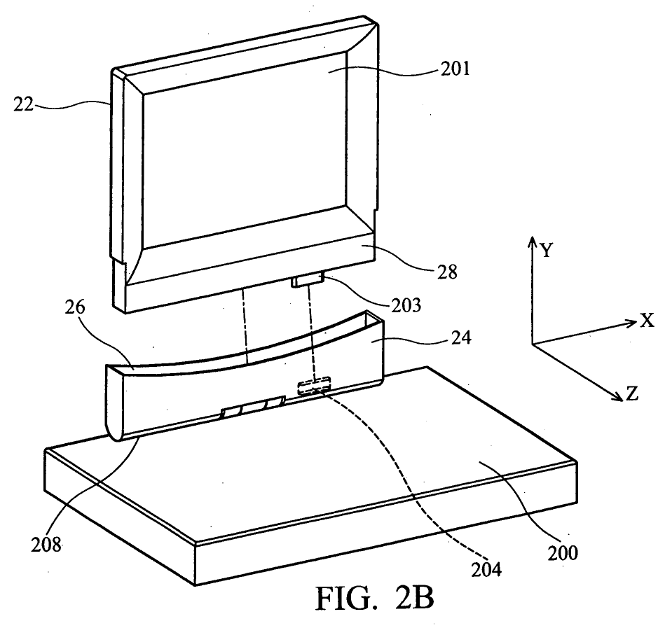

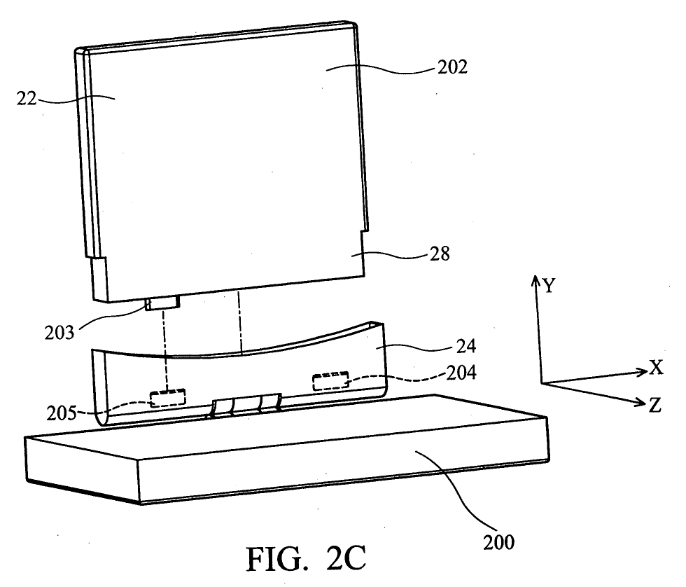

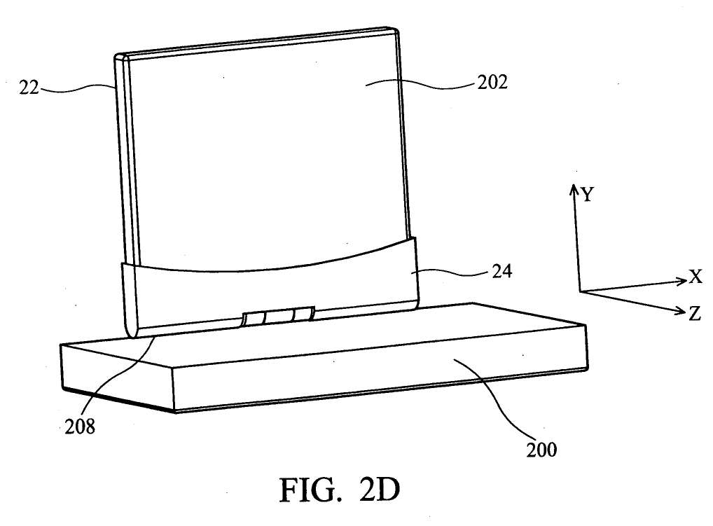

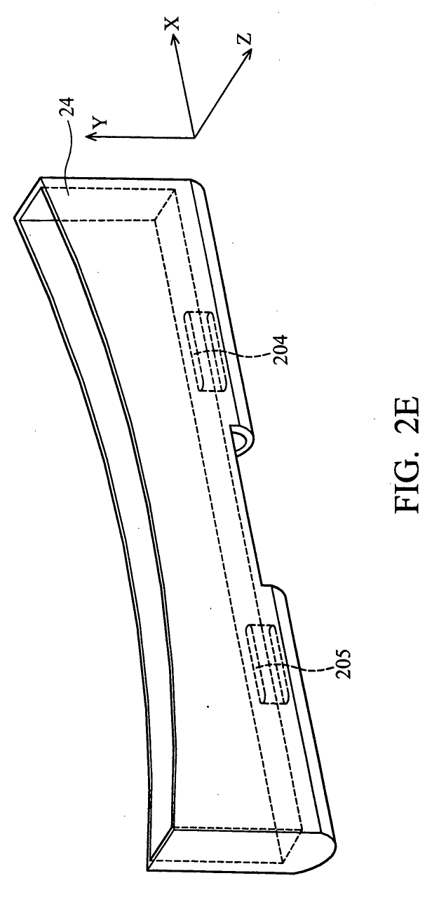

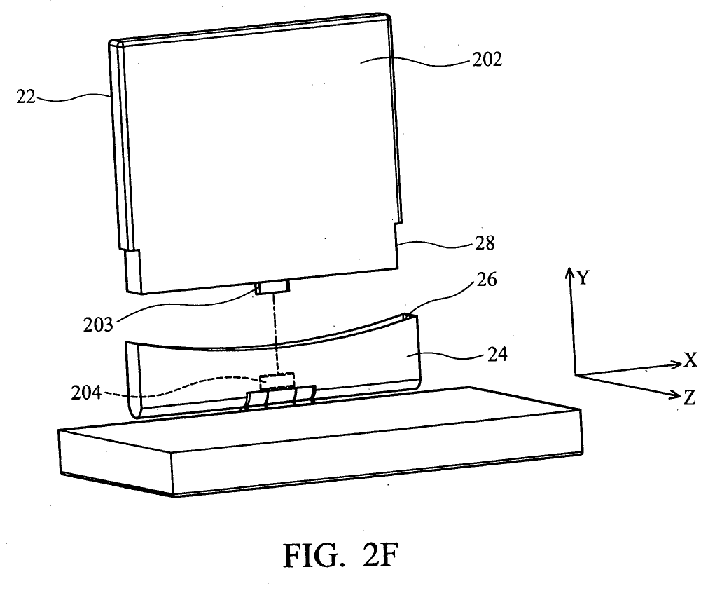

FIG. 2A is a schematic front view of the display according to the first embodiment of the present invention. The display of the present invention is applicable to a portable computer 20 (or a desktop computer) with a display. The portable computer 20 is mainly composed of a body 200 and a display. The display includes a base 24 and a panel 22. The base 24 is rotatably connected to the body. The panel 22 is detachably connected to the base 24. In this embodiment, the front surface 201 of the panel 22 faces to a +Z direction (referred to a first direction), the front surface 201 is the viewing side of the panel 22, and the back surface 202 faces to a −Z direction (referred to a second direction). That is, the first and second directions are opposite each other. The panel 22 is disposed on the base 24 facing either the first (+Z) or the second (−Z) direction. A shaft 208 is used to connect the base 24 to the body 200. Thus, the base 24 is rotated around the X-axis via the shaft 208.

FIGS. 2A to 2D successively show motions of changing direction of the display as follows.

FIG. 2A shows a schematic front view of the display, and FIG. 2B shows the panel 22 is detached from the base 24 before rotating the display.

Next, as shown in FIG. 2C, the panel 22 is moved and the front surface 201 of the panel 22 is faced to the second direction (−Z direction); That is, the back surface 202 faces +Z direction.

Finally, the panel 22 is electrically connected with the base 24 via a plurality of connectors, as shown in FIG. 2D.

As shown in FIG. 2B, the base 24 has a groove 26 therein. The panel 22 has a protrusion 28. The panel 22 is connected to the base 24 by inserting the protrusion 28 in the groove 26. The panel 22 further includes a first connector 203, disposed on the protrusion 28.

FIG. 2E is an enlarged view of the base 24. The base 24 has a second connector 204 and a third connector 205. Both connectors 204, 205 are disposed in the groove 26.

Referring to FIG. 2B, when the front surface 201 of the panel 22 is faced to the first direction (+z direction) to connect with the base 24, the first connector 203 is electrically connected to the second connector 204. Further, as shown in FIG. 2c, the panel 22 is rotated by 180 degree, the first connector 203 is electrically connected to the third connector 205 when the back surface 202 of the panel 22 is faced to the first direction (+Z direction). Finally, as shown in FIG. 2D, the display is completely installed. Thus, due to the detachable connection of the display, the panel 22 can be freely rotated in any direction unrestricted by the body or wires therebetween.

Also, according to the above embodiment, another alternative is available, that is, the positions of the connectors can be interchanged. The first and second connectors can be disposed on the protrusion 28 of, the panel 22. The third connector can be disposed in the groove 26 of the base 24. When the front surface of the panel 22 is faced to the first direction to connect with the base 24, the first connector is electrically connected to the third connector. When the front surface of the panel 22 is faced to the second direction, the second connector is electrically connected to the third connector.

The first embodiment can be further modified into a simplified case, as shown in FIG. 2F. A first connector 203 is disposed on the protrusion 28 of the panel 22, and a second connector 204 is disposed in the groove 26 of the base 24. When the panel 22 faces either the first or the second direction, the first connector 203 electrically connects with the second connector 204. That is, only two connectors 203, 204 are necessary to connect the panel 22 and the base 24 in either +Z or −Z direction.

### Second Embodiment

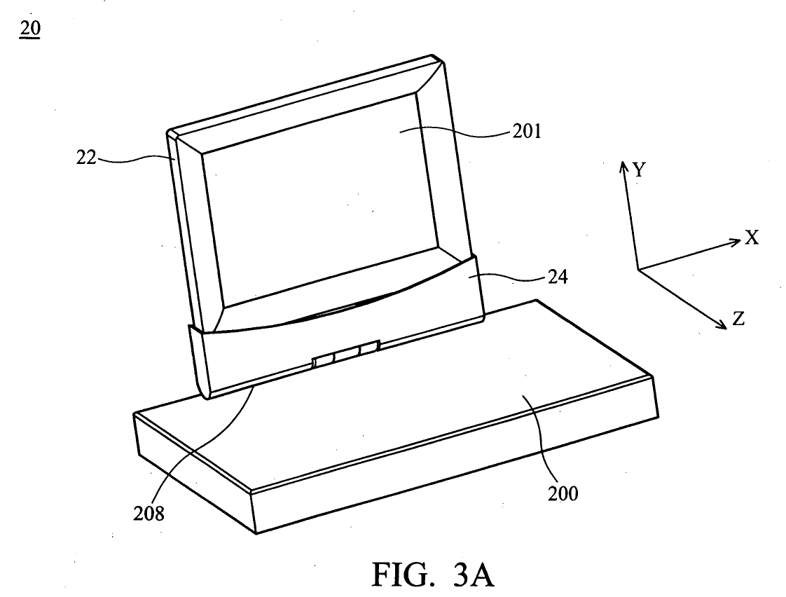

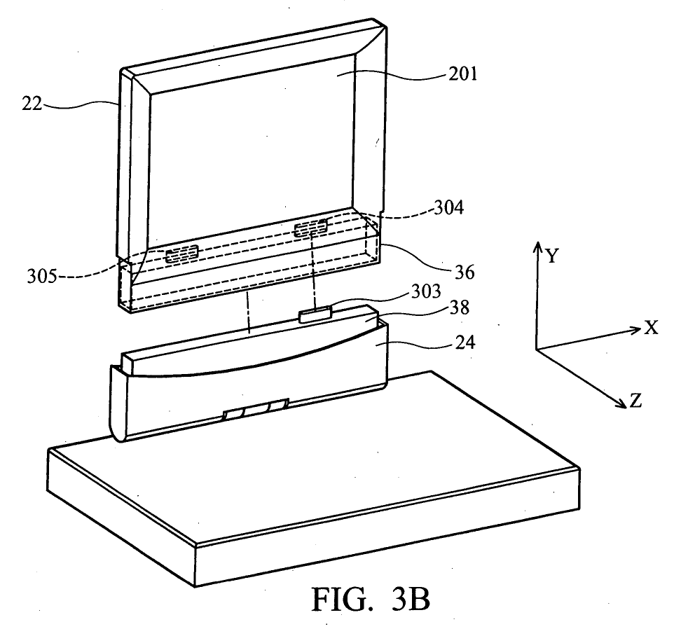

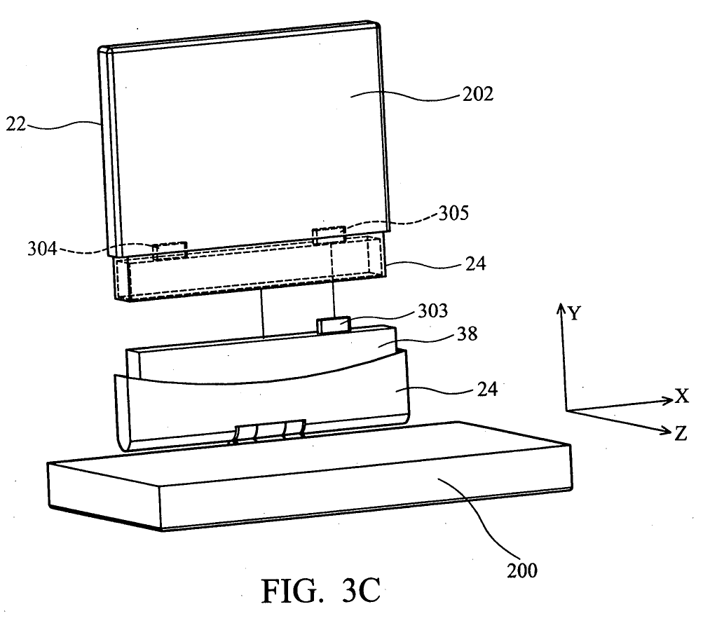

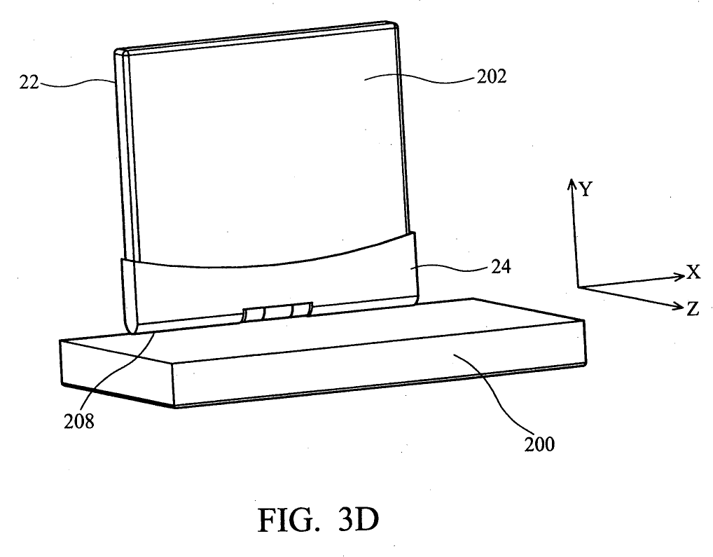

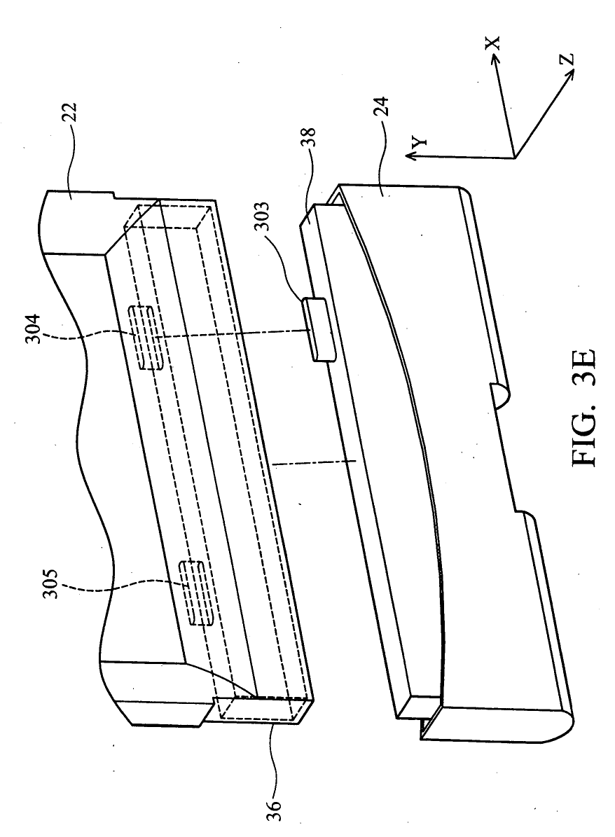

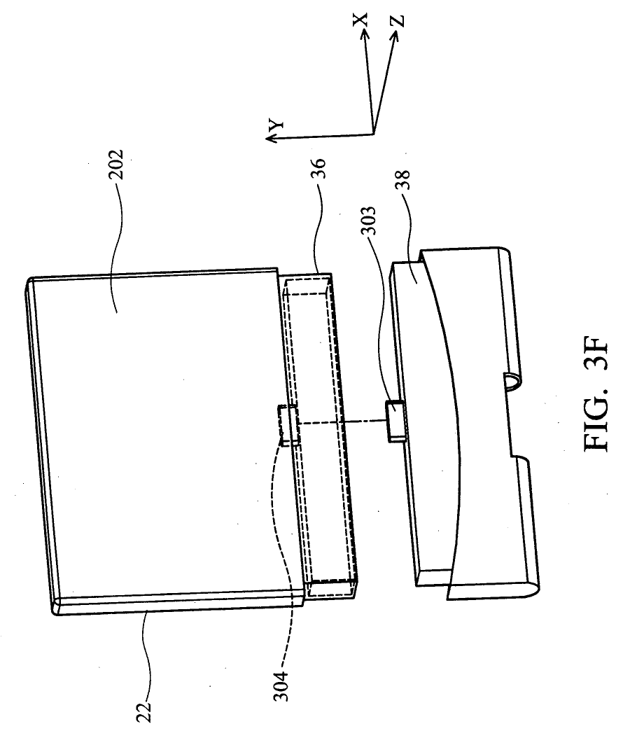

The second embodiment is similar to the first embodiment. FIGS. 3A˜3D are schematic views of the display according to the second embodiment of the present invention. Referring to FIG. 3A, a portable computer 20 (or a desktop computer) has a body 200 and a display. The display has a base 24 and a panel 22. The main difference between the two embodiments is that the groove 36 is disposed in the panel 22, and the base 24 has the protrusion 38, as shown in FIG. 3B. The panel 22 is connected to the base 24 by inserting the protrusion 38 into the groove 36. FIGS. 3A to 3D successively show the motions of changing directions of the display. The steps of changing direction and the elements of the display are the same as those of the first embodiment, and thus, detailed description is omitted.

FIG. 3E is an enlarged view of the base 24. The base 24 has a first connector 303 disposed on the protrusion 38. The panel 22 has a second and a third connector 304, 305 disposed in the groove 36.

As shown in FIG. 3B, when the front surface 201 of the panel 22 is faced to the first direction to connect with the base 24, the first connector 303 is electrically connected to the second connector 304.

Referring to FIG. 3C, when the panel 22 is rotated by 180 degree, the first connector 303 is electrically connected to the third connector 305. Finally, as shown in FIG. 3D, the display is completely installed. Thus, due to the detachable connection of the display, the panel 22 can be freely rotated in any direction unrestricted by the body or any wires therebetween.

Also, according to the second embodiment, another alternative is available, that is, the positions of the connectors can be interchanged. The first and second connectors are disposed on the protrusion of the base 24, and the third connector is disposed in the groove 36 of the panel. When the front surface of the panel 22 is faced to the first direction to connect the panel 22 to the base 24, the first connector is electrically connected to the third connector. When the front surface of the panel 22 is faced to the second direction to connect the panel 22 to the base 24, the second connector is electrically connected to the third connector.

The second embodiment can be further modified into a simplified case, as shown in FIG. 3F. A first connector is disposed on the protrusion 38 of the base 24, and a second connector disposed in the groove 36 of the panel 22. When the panel 22 faces either the first or the second direction, the first connector 303 is electrically connected with the second connector 304, such that only two connectors 303, 304 are necessary.

### Third Embodiment

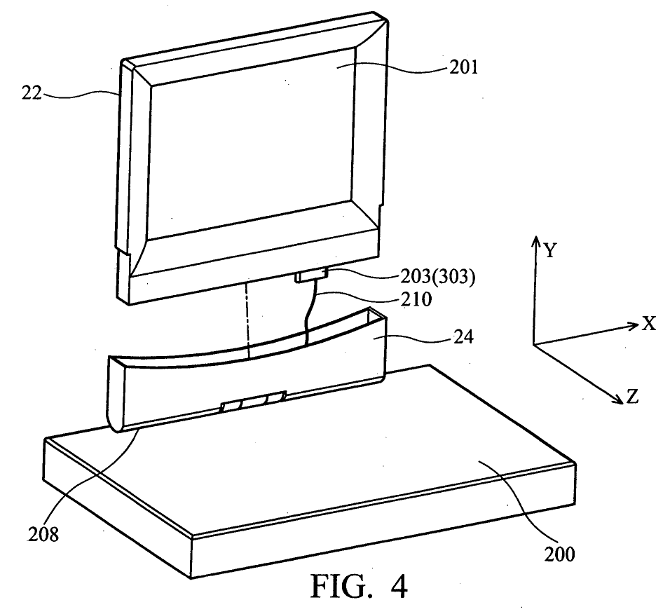

FIG. 4 is a schematic view of the display with a wire according to the third embodiment of the present invention. All the symbols on this figure are the same as those in the first and second embodiments and they are not mentioned again. The display 22 according to the third embodiment further includes a wire 210. When the panel 22 and the base are separated, the wire 210 is used to connect the panel 22 and the base 24. One end of the wire 210 is connected to the first connector 203 or 303 of the panel 22, and the other end is connected to the second connector of the base 24. The length of the wire 210 can be varied. As a result, the display 22 is not limited by the location of the base 24 or the body 200.

### Fourth Embodiment

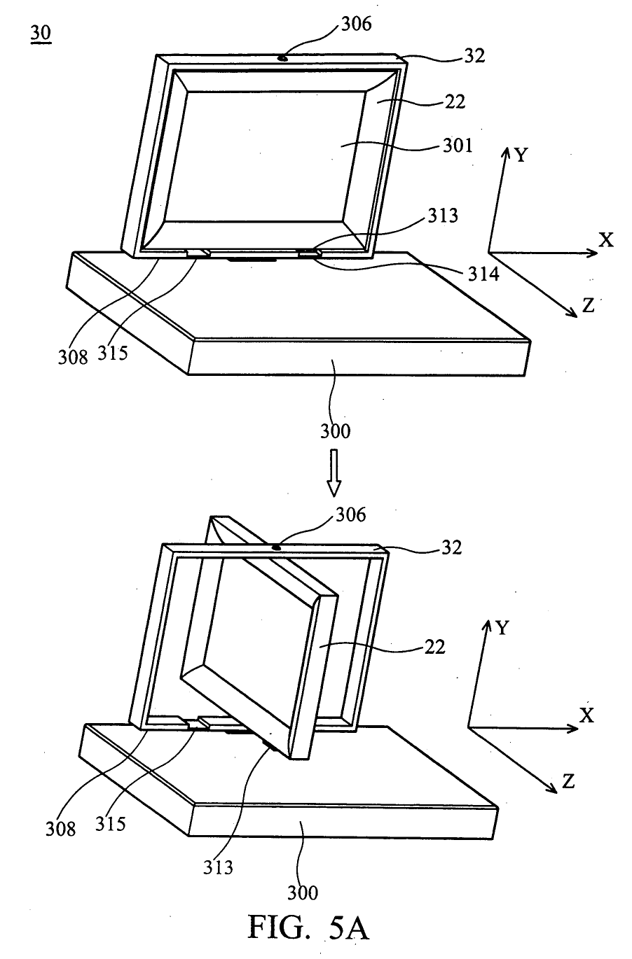

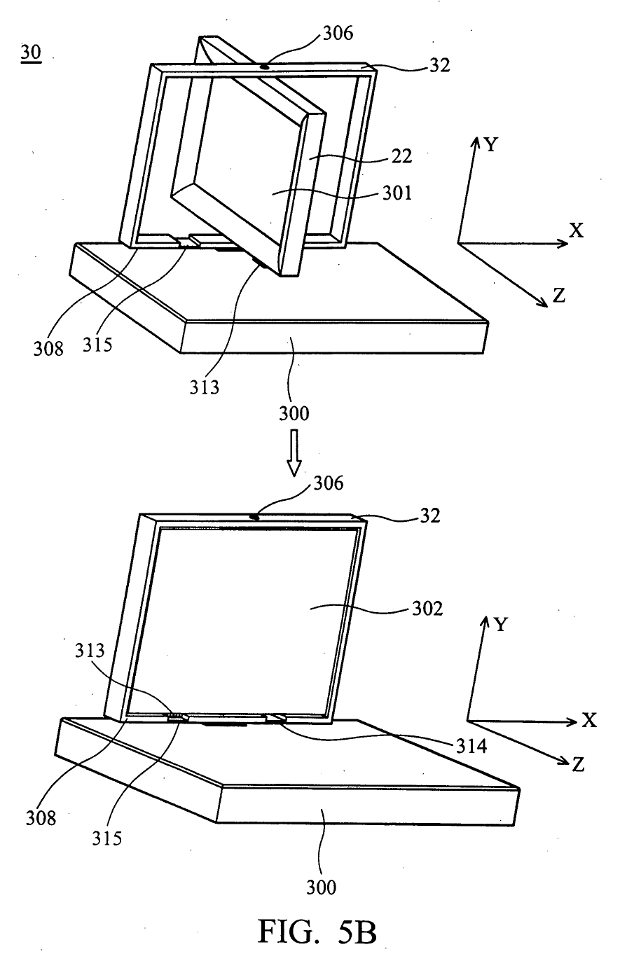

FIGS. 5a and 5b are successively rotated views of the display according to the fourth embodiment of the present invention. The display can be applicable to a portable computer 30 composed of a body 300, a frame 32, and a panel 22. The panel 22 is rotatably disposed within the frame 32 by a first shaft 306. The frame 32 is rotatably disposed on the body 300 by a second shaft 308. The frame 32 can be rotated around the X-axis by the second shaft 308, and the panel 22 can be rotated freely around the Y-axis by the first shaft 306 so that the panel is operated when facing to a first or a second direction. The first direction is opposite to and the second direction.

As shown in FIG. 5a, the panel 22 has a first connector 313, and the frame has second and third connectors 314, 315. When the front surface 301 of the panel 22 faces the first direction (+Z direction), the first connector 313 electrically connects with the second connector 314.

As shown in FIG. 5b, when the front surface 301 of the panel 22 faces the second direction (−Z direction), the first connector 313 electrically connects with the third connector 315.

The locations of the connectors of the fourth embodiment are interchangeable. This variation is not shown in any drawing. The first and second connectors may be disposed on the panel 22, and the frame 32 can includes a third connector. When the panel 22 is faced to the first direction, the first and third connectors are electrically connected to each other. When the panel 22 is faced to the second direction, the second and the third connectors are electrically connected.

The fourth embodiment may be modified into another simplified model. In this simplified embodiment, the first shaft 306 is hollow, and a wire (not shown) is disposed therein. The panel 22 is electrically connected with the body 300 through the wire.

The panel 22 of the embodiment is also applicable to a desktop computer. The panel 22 is also connected with the frame by a shaft 306; other elements and structures remain unchanged.

The advantage of the present invention is that the display is not limited by the location of the body or the base. The panel can be freely placed in different locations or rotated in any direction. Also, the addition of the wire extends the connection between the panel and the body so that the angle of rotation of the display is unrestricted.

When the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1-11. (canceled)

12. A display, comprising:
a frame; and
a panel having a first shaft rotatably disposed within the frame, wherein the panel is rotated freely by a Y-axis direction via the first shaft, so that the panel is operated when facing to a first or a second direction, and the first direction is opposite to and the second direction.

13. The display as claimed in claim 12, wherein the frame has a first connector, the panel has a second connector, and the first connector is electrically connected with the second connector when the panel is faced to the first direction.

14. The display as claimed in claim 13, wherein the frame has a third connector, the first connector is electrically connected with the second connector when the panel is faced to the first direction, and the second connector is electrically connected with the third connector when the panel faces the second direction.

15. The display as claimed in claim 13, wherein the panel has a third connector, the second connector is electrically connected with the first connector when the panel is faced to the first direction, and the third connector is electrically connected with the first connector when the panel faces the second direction.

16. The display as claimed in claim 12, further comprising:
a body, the frame being rotatably connected to the body; and
a second shaft, by which the panel being rotatably connected to the frame, and wherein the frame is rotated by an X-axis, the panel is freely rotated about the Y-axis, and the X-axis is substantially vertical to the Y-axis.

17. The display as claimed in claim 16, wherein the first shaft is hollow and the display further comprises a wire disposed in the first shaft to electrically connect the panel to the base.
